(19) United States
(12) Patent Application Publication
(10) Pub. No.: US 2019/0044011 A1
(43) Pub. Date: Feb. 7, 2019

(54) RAPID DEPLOY SOLAR ARRAY

(71) Applicants: Kenneth Pereira, Woodlake, CA (US); Jason Timothy Wadlington, Madera, CA (US); Bruce Kopitar, Lincoln, KS (US); Mike Huerta, Visalia, CA (US)

(72) Inventors: Kenneth Pereira, Woodlake, CA (US); Jason Timothy Wadlington, Madera, CA (US); Bruce Kopitar, Lincoln, KS (US); Mike Huerta, Visalia, CA (US)

(21) Appl. No.: 16/051,476

(22) Filed: Jul. 31, 2018

Related U.S. Application Data
(60) Provisional application No. 62/540,035, filed on Aug. 1, 2017.

(51) Int. Cl. H01L 31/0475; H01L 31/047; H02S 40/36; H02S 30/10

(52) U.S. Cl. CPC H01L 31/0475; H02S 30/10; H02S 40/36; H01L 31/047

(57) ABSTRACT

A deployable solar array is built in a rectangular frame. First and second pairs of end-support members are mounted to opposite ends of the frame rotatable from a stowed position to a deployed position. A plurality of solar panel assemblies including a plurality of photovoltaic solar cell arrays are vertically stacked in stowed positions within the rectangular frame and are individually moveable along and supported by the end support members from their stowed positions to deployed positions.

### CROSS-REFERENCE TO RELATED APPLICATIONS

The present Application claims priority from U.S. Provisional Patent Application Ser. No. 62/540,035, filed on Aug. 1, 2017, the contents of which are incorporated in this disclosure by reference in its entirety.

### BACKGROUND

The present invention relates to large and medium scale portable deployable photoelectric solar arrays. More particularly, the present invention relates to such photoelectric solar arrays that are rapidly deployable.

### BRIEF DESCRIPTION

According to one aspect of the present invention, a portable rapid deployable photoelectric solar array is disclosed.

According to another aspect of the invention, the portable rapid deployable solar array is deployable from a frame in the form of a rectangular prism. In some embodiments of the present invention, the frame may have the dimensions of an ISO shipping container. Specifications for such shipping containers are found in ISO International Standard 668 for intermodal freight shipping containers. This specification is incorporated herein by reference. For transport, the rapidly deployable solar array of the present invention is able to be collapsed and housed within the volume defined by the rectangular frame. For usage, the container unfolds and expands a photoelectric solar array that is supported above ground by the structure of the container.

According to another aspect of the present invention, the solar photoelectric array fields deploy to either side of the container structure supported by cantilevered beams that are supported by suspension cables attached to vertical support affixed to the container structure. Once the cantilevered beams are deployed and supported by the suspension cables, the solar photoelectric array fields are then moveable into the deployed position along the length of the cantilevered beams. The solar photoelectric array fields include a plurality of solar photoelectric arrays of solar panels that are affixed to individual relocatable beams allowing the solar array assemblies to be easily deployed. The solar panels are coupled to their respective supporting beams using a pivoting structure which allows for optimal position of the solar arrays for the purpose of collecting maximum solar power. These relocatable beams are positioned at an elevation that makes deployment easy while allowing personnel to work safely from the ground.

According to another aspect of the present invention, the entire deployed solar field is able to be elevated using the container structure powered by actuators. Elevating the structure increases usable space, provides shelter, provides cover, reduces the potential for tampering, and/or increases the visibility of the system for various purposes.

### BRIEF DESCRIPTION OF THE DRAWING FIGURES

The invention will be explained in more detail in the following with reference to embodiments and to the drawing in which are shown:

FIG. 1 is a drawing showing a perspective view of an exemplary rapidly deployable solar array stowed and ready for transport;

FIG. 2 is a drawing showing a side view of an exemplary rapidly deployable solar array stowed and ready for transport;

FIG. 3 is a drawing showing an end view of both ends of an exemplary rapidly deployable solar array with a plurality of solar panel assemblies stowed and ready for transport or deployment in accordance with the present invention;

FIG. 4A is a perspective rear-facing view of a typical solar panel assembly suitable for use in accordance with the present invention;

FIG. 4B is a drawing showing a magnified perspective view of an illustrative solar panel pivot point latch suitable for use in the present invention;

FIG. 5A is a drawing showing a perspective view of an exemplary rapidly deployable solar array with a plurality of solar panel assemblies stowed with the cable suspension upright members shown deployed in an operating position in accordance with the present invention;

FIG. 5B is a drawing showing a magnified perspective view of a portion of the rapidly deployable solar array of FIG. 5A illustrating how the cable suspension upright members may be fastened in their deployed positions;

FIG. 6 is drawing showing a perspective view of an exemplary rapidly deployable solar array with cantilever solar panel assembly support beams shown in a deployed position suspended by support cables from the cable suspension upright members in accordance with the present invention;

FIG. 7 is a drawing showing a perspective view of an exemplary rapidly deployable solar array with opposing outer solar panel assemblies shown in a deployed position in accordance with the present invention;

FIG. 8 is a drawing showing a perspective view of an exemplary rapidly deployable solar array with all of the solar panel assemblies shown in a deployed position and angled for optimized solar energy collection in accordance with the present invention;

FIGS. 9A and 9B are drawings showing an enlarged perspective views of portions of an illustrative cantilever solar panel assembly support beam suitable for use in accordance with the present invention; and

FIG. 10 is a drawing showing a perspective view of an exemplary rapidly deployable solar array with solar arrays in fully deployed positions and angled for optimized solar energy collection, the array elevated to provide usable space below the array in accordance with the present invention.

### DETAILED DESCRIPTION

Persons of ordinary skill in the art will realize that the following description of the present invention is illustrative only and not in any way limiting. Other embodiments of the invention will readily suggest themselves to such skilled persons.

The present invention is a rapidly deployable solar array (RDSA) that is a solar photovoltaic generating charging system and is contained within and deployed from a frame in the form of a rectangular prism. In one embodiment, the frame has the physical dimensions, construction and layout of a typical ISO container. For the purpose of transport, the RDSA is configured to be collapsed and occupy the volume of a typical ISO container. In some embodiments, the RDSA can be housed in a typical ISO container and is deployed by unfolding the container and expanding a large solar array that is supported above ground by the structure of the frame.

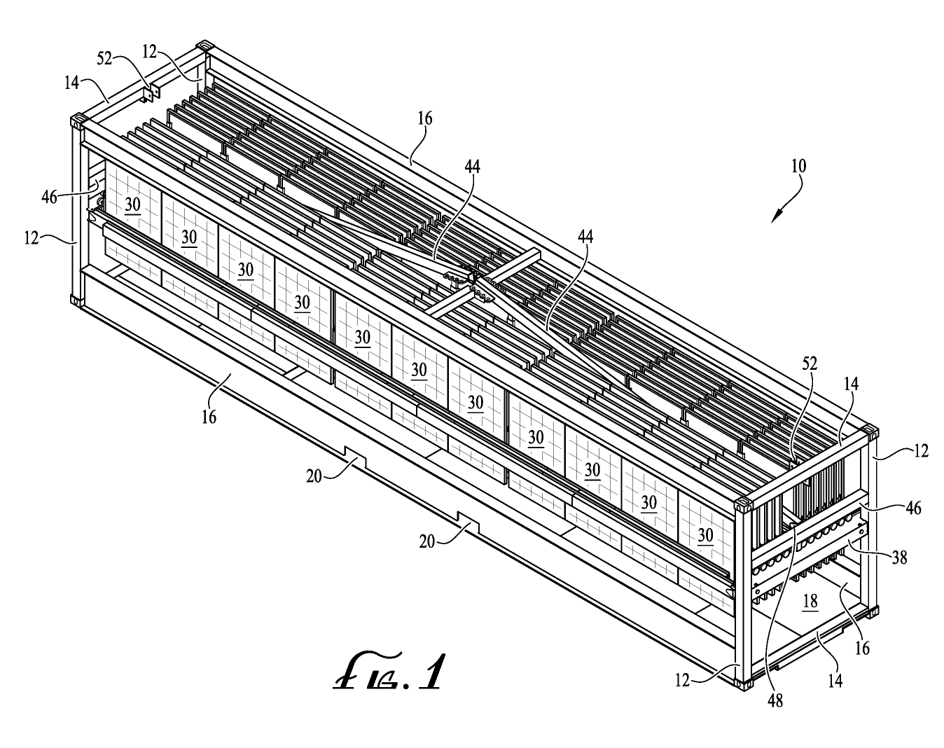

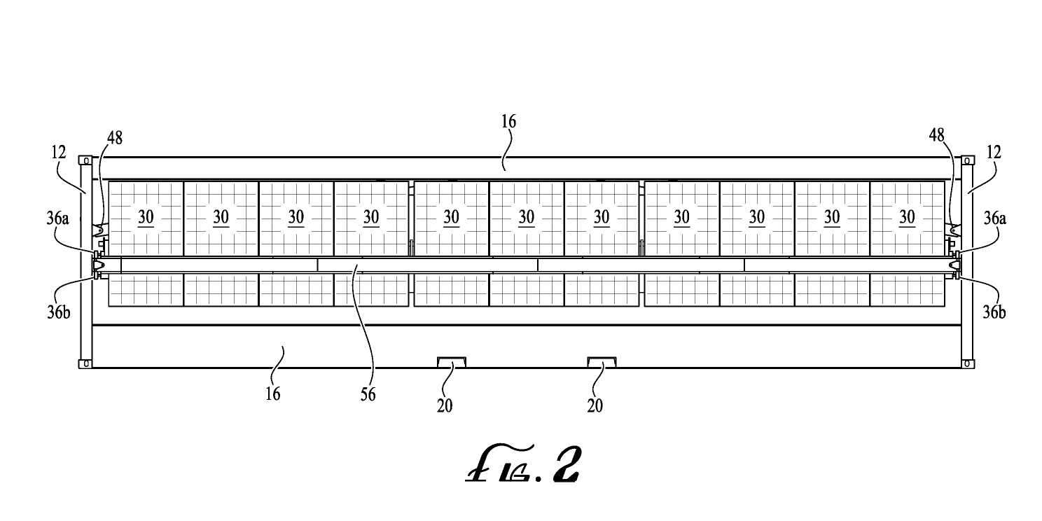

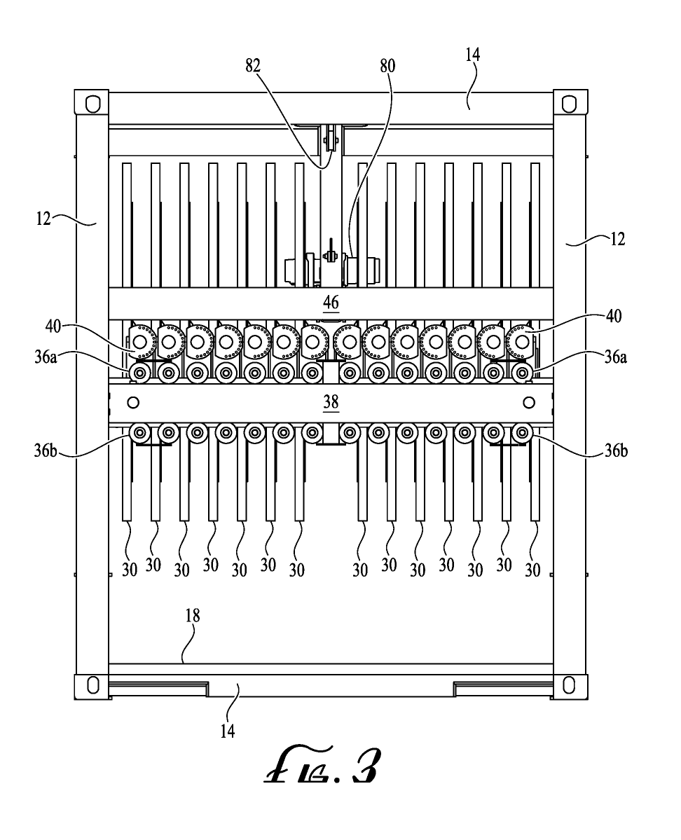

Referring first together to FIGS. 1 through 4B, the RDSA 10 is constructed on a rectangular-prism-shaped frame including vertical members 12, horizontal end members 14 and horizontal side members 16. In the embodiment depicted in FIG. 1, The bottom of the frame includes a platform 18 which may be used for battery storage and placement of control electronics. As depicted in FIG. 1, in accordance with one embodiment of the invention the bottom side members 16 of the frame may include a pair of spaced apart forklift guides 20 to allow for easy moving of the RDSA. FIG. 1 shows a perspective view of an exemplary RDSA 10 stowed and ready for transport. FIG. 2 shows a side view of an exemplary RDSA 10 stowed and ready for transport. FIG. 3 shows an end view of an exemplary RDSA 10 with a plurality of solar panel assemblies stowed and ready for transport or deployment in accordance with the present invention. Persons of ordinary skill in the art will appreciate that FIG. 3 is meant to depict the view from both ends of the RDSA 10.

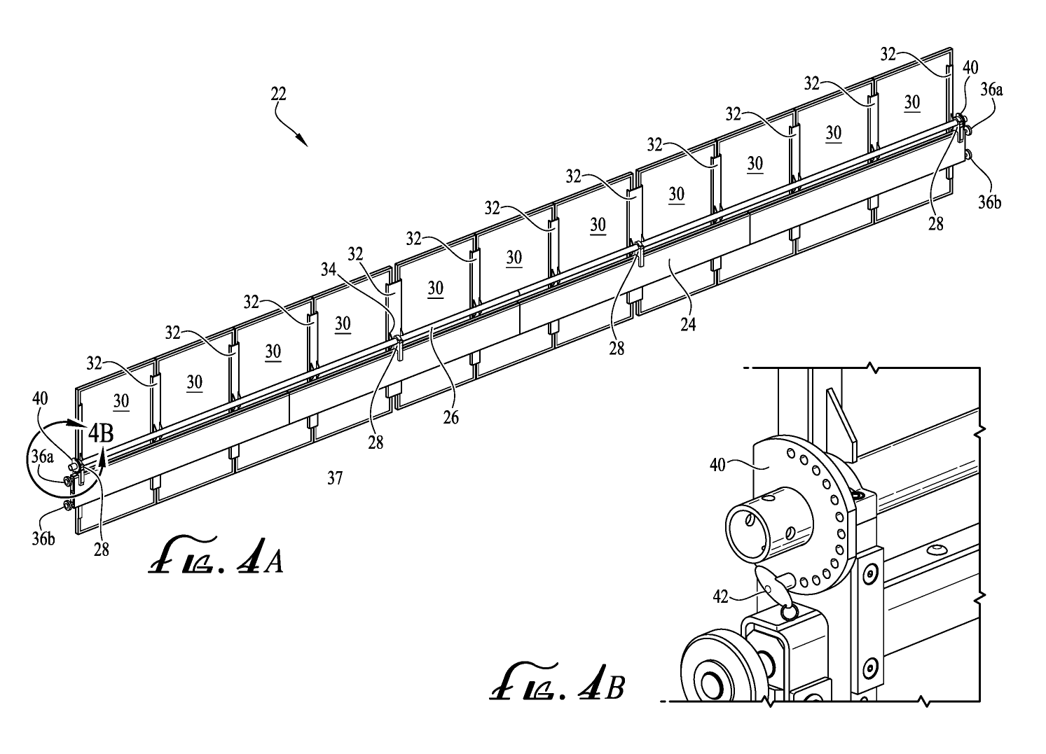

FIG. 4A shows a perspective rear-facing view of a typical solar panel assembly 22 suitable for use in an RDSA in accordance with the present invention. The solar panel assembly is built on a solar panel assembly frame 24. A solar panel mounting shaft 26 is coupled to the solar panel assembly frame 24 by a plurality of bearings 28. Solar panels 30 are coupled to the solar panel mounting shaft 26 by solar panel frames 32 fastened, for example welded, to the shaft one instance of which is indicated at reference numeral 34. The solar panels 30 may be fastened to the solar panel frames 32 using bolts or other mounting hardware. The solar panels 30 may be typical arrays of solar photovoltaic cells as is known in the art.

As shown in FIG. 3, both ends of each solar panel assembly frame 24 include a pair of spaced apart rollers including upper rollers 36a and lower rollers 36b. When the solar panel assemblies are in their stowed positions within the frame, the spaced apart rollers on each end of the solar panel assembly frame 24 engage a roller guide 38.

As most easily seen in FIG. 4B, a solar panel pivot point latch 40 is axially mounted at each end of the solar panel mounting shaft 26. This latch may consist of a flat circular plate having a plurality of holes radially arranged around its periphery. When in its deployed position, the solar panel assembly may be rotated about the solar panel mounting shaft 26 to tilt the faces of the solar panels 30 to an angular position selected to maximize solar energy collection and a spring-loaded pin 42 is driven into one of the plurality of holes to lock the solar panel assembly into pace at the selected angular position. Persons of ordinary skill in the art will appreciate that the angular positions of the solar panels 30 may be controlled by a motor and solar tracking system to continually present the solar panels at optimal energy collection angles.

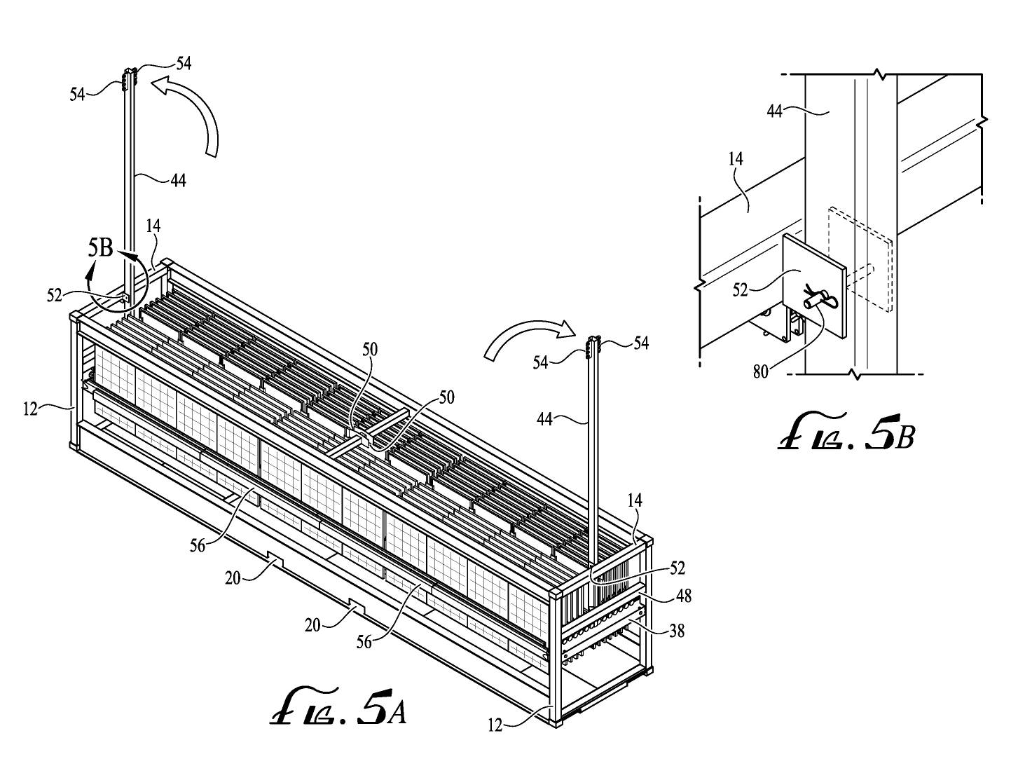

A cable suspension upright member 44 is mounted in the center of each end of the frame. In the embodiment shown in FIG. 1, the cable suspension upright members 44 are each pivotally mounted to a horizontal cross member 46 at a pivot 48 connected between the two vertical members 12 and are held in cradles 50 (seen most easily in FIG. 5) when the RDSA is in its stowed configuration. FIG. 1 shows both cable suspension upright members 44 in their stowed positions.

FIG. 5A is a drawing showing a perspective view of the RDSA 10 of FIGS. 1 through 5 with the cable suspension upright members 44 shown deployed in an operating position in accordance with the present invention. As most easily seen in FIG. 5B, each cable suspension upright member 44 may be locked into its deployed upright vertical positions between a pair of opposed brackets 52 (shown also in FIG. 1) using, for example, a pin engaging the cable suspension upright member 44 through holes in the pair of opposed brackets 52. Each cable suspension upright member 44 includes an opposed set of suspension cable anchor points 54.

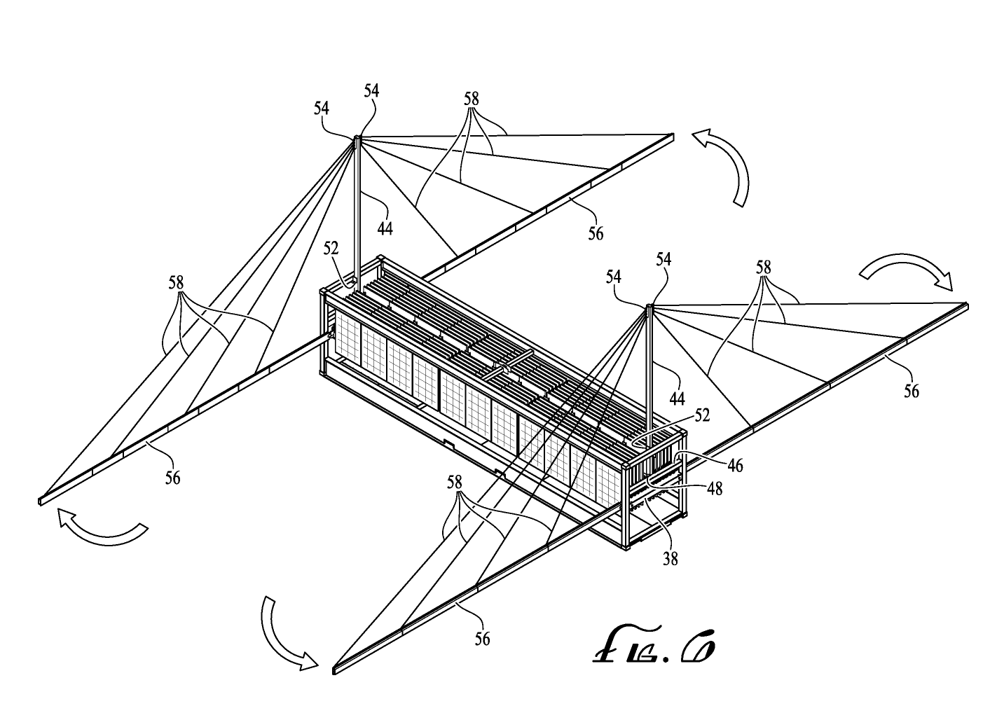

A cantilever solar panel assembly support beam 56 is pivotally mounted to each vertical member 12 of the frame. FIG. 5A shows the cantilever solar panel assembly support beams 56 on one side of the RDSA 10. FIG. 6 shows all four of the cantilever solar panel assembly support beams 56 in their deployed positions supported at several places along their length by suspension cables 58 terminated at the suspension points 54 on the cable suspension upright members 44. Persons of ordinary skill in the art will appreciate that the number and positioning of the support cables 58 along the lengths of the cantilever solar panel assembly support beams 56 will depend on ordinary mechanical engineering weight loading concerns.

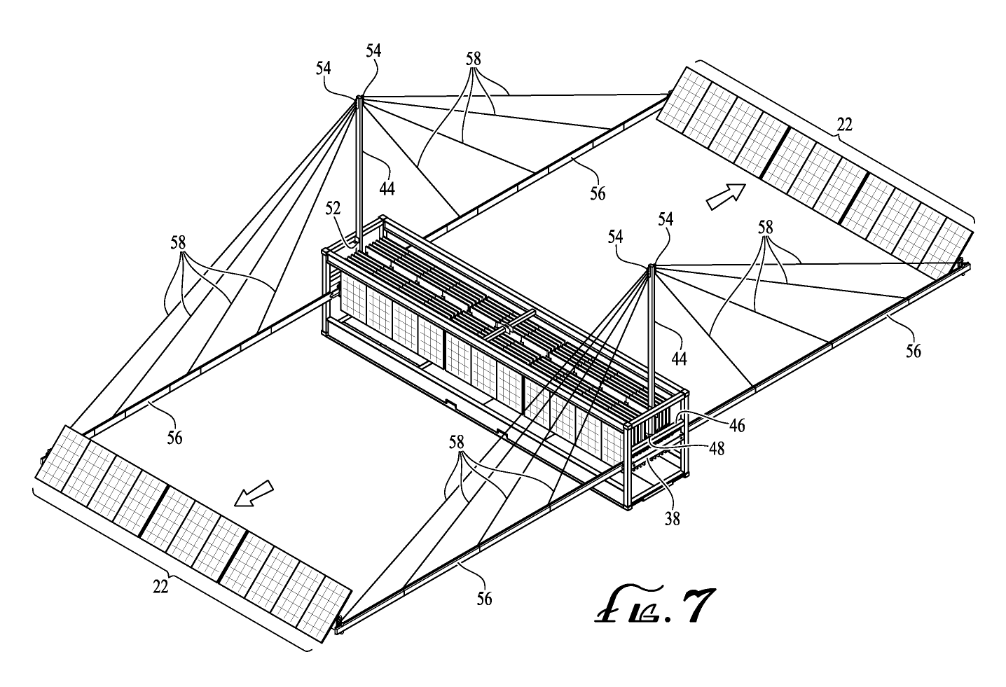

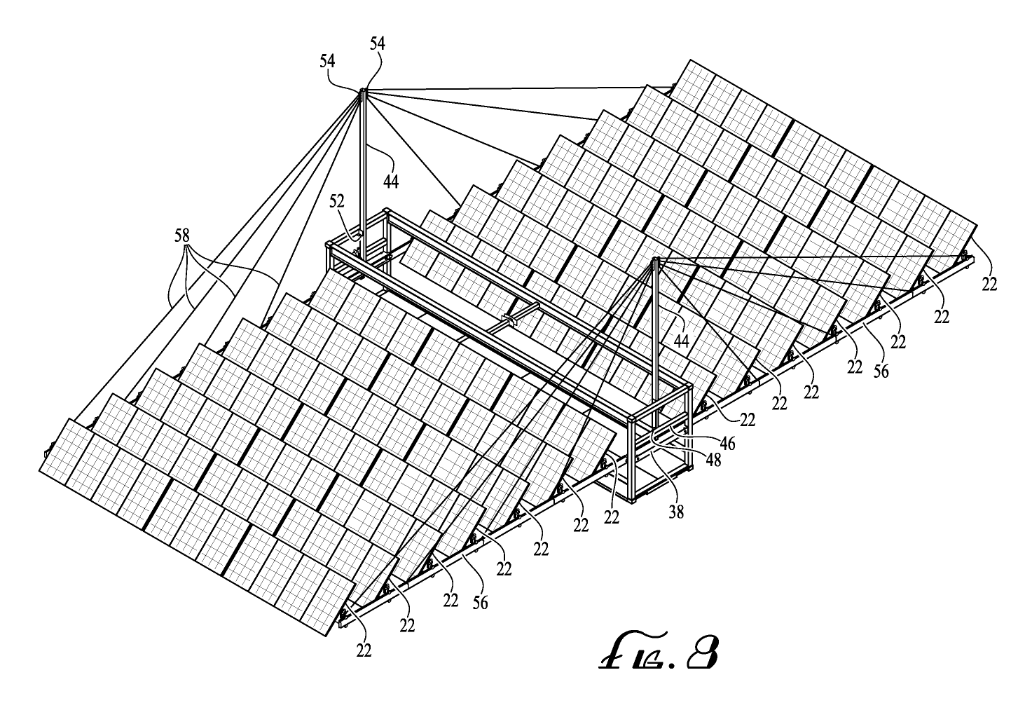

The solar panel assemblies 22 deploy to either side of the container structure supported by the cantilever solar panel assembly support beams 56. FIG. 7 shows partial deployment of the solar panel assemblies 22 in that the outer solar panel assemblies 22 on both sides of the RDSA have been deployed and angled to optimally collect solar radiation. Each of the solar panel assemblies 22 is rolled out on the rollers 36a and 36b along the pairs of cantilever solar panel assembly support beams 56 on both sides of the RDSA. The cantilever solar panel assembly support beams 56 have the same width as and are aligned with the roller guides 38 to allow the rollers 36a and 36b to smoothly transition between the roller guides 38 and the cantilever solar panel assembly support beams 56. The solar panel assemblies 22 are positioned and may be latched into place at predetermined locations along the lengths of the cantilever solar panel assembly support beams 56. FIG. 8 shows the solar panel assemblies 22 completely deployed on both sides of the RDSA and angled to optimally collect solar radiation. Persons of ordinary skill in the art will appreciate that, while the particular embodiments shown employ seven solar panel assemblies 22 on either side, any number of solar panel assemblies 22 may be used depending on the power needs of the particular application.

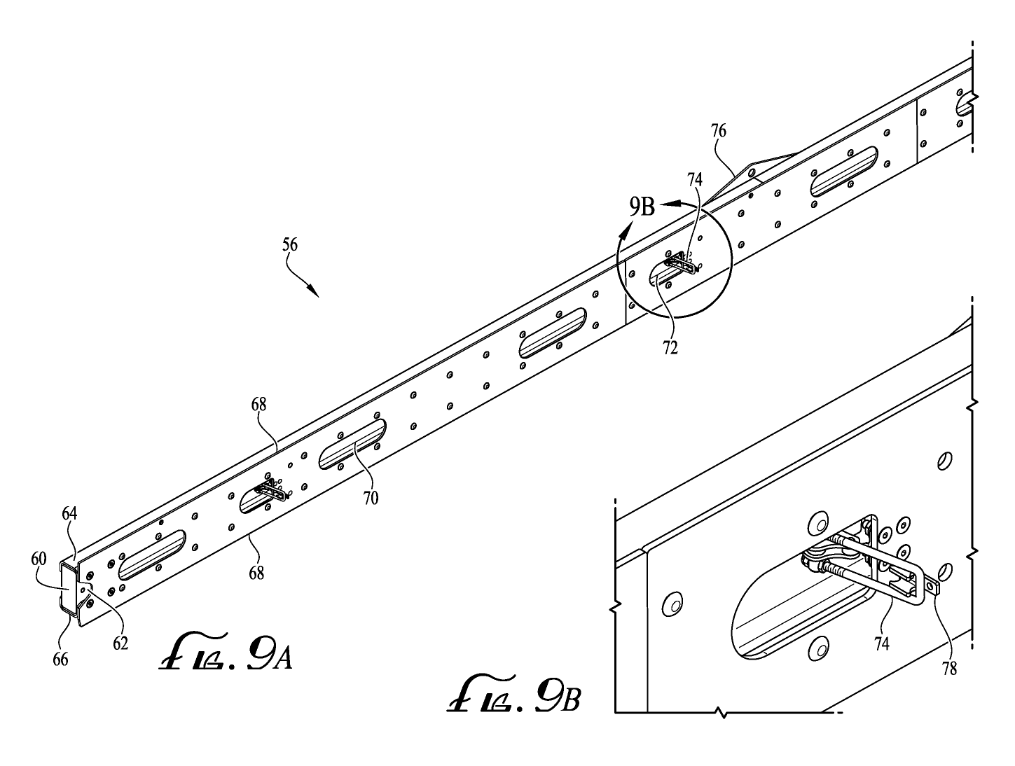

Referring now to FIGS. 9A and 9B, drawings show enlarged perspective views of portions of an illustrative cantilever solar panel assembly support beam 56 suitable for use in accordance with the present invention. According to one aspect of the invention shown in FIG. 9A, the cantilever solar panel assembly support beam 56 may include a member 60 (showing a hinge plate 62 at the end of the member 60 that connects to the frame is shown) having an upper roller contact surface 64 along which the upper rollers 36a of the solar panel assembly frames 24 (FIG. 3) may travel and a lower roller contact surface 66 along which the lower rollers 36b of the solar panel assembly frames 24 (FIG. 3) may travel. Top and bottom flanges 68, which may be integral with the member 60 or may be fastened to the member 60 are provided on each cantilever solar panel assembly support beam 56 and help maintain the alignment of the rollers 36a and 36b as the solar panel assembly frames 24 travel into position during their deployment.

Slots 70 may be provided to reduce the weight of the cantilever solar panel assembly support beams 56. This technique is well known in the art. Some slots 72 may serve to provide latches 74 to lock the cantilever solar panel assembly support beams 56 into place once they are properly positioned. A suspension cable eye 76 is used as an attachment point for one of the suspension cables 58.

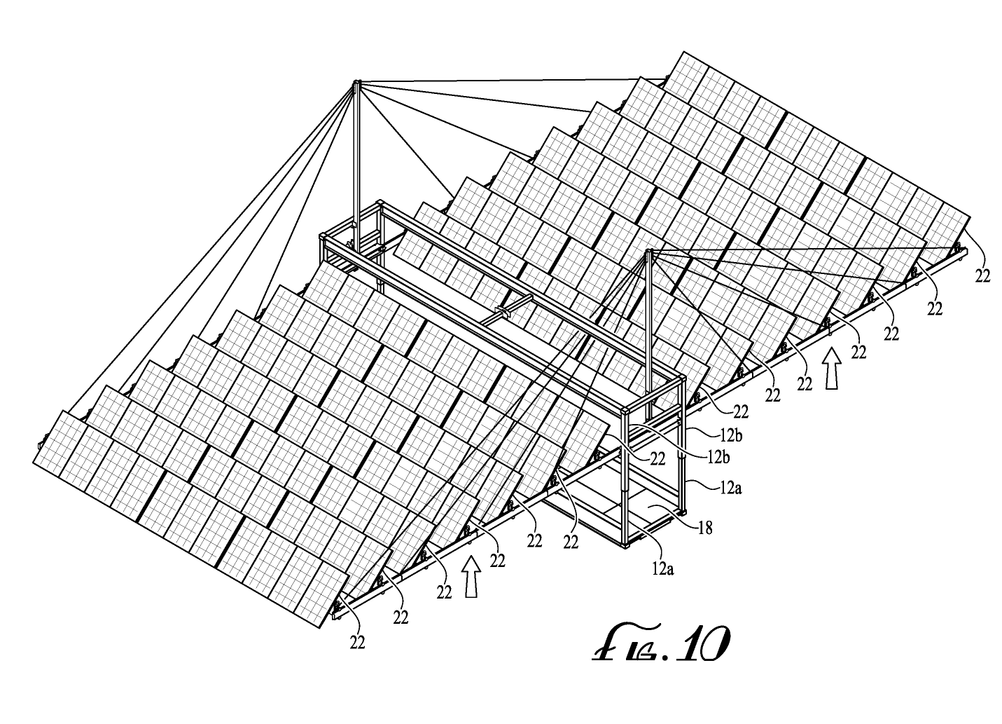

FIG. 9B is a drawing showing a magnified perspective view of an illustrative latch 74 that may be used for this purpose although persons of ordinary skill in the art will appreciate that other latch mechanisms and indeed other fastening mechanisms may serve this purpose equally well. The particular latch shown in FIG. 9B is a right-angle latch style toggle clamp Part No. 5135A42 available from McMaster Carr of Santa Fe Springs, Calif. The hasp 78 shown in FIG. 9B is attached to the solar panel assembly frames 24 to engage the latch portion shown in FIG. 9B and secure them in place along the cantilever solar panel assembly support beams 56. Persons of ordinary skill in the art will appreciate that the hasps 78 at the ends of the solar panel assembly frames 24 may be engaged with latches disposed in the ends of the frame (not shown) to secure the solar panel assembly frames 24 when stowed for transport. In accordance with some embodiment of the present invention, the entire RDSA is configured to be elevated by actuators. According to one non-limiting example embodiment shown in FIG. 10, each of the vertical members 12 includes two telescoping sections 12a and 12b. A hydraulic cylinder disposed in each section 12a and coupled to its telescoping section 12b may be activated to raise the RDSA in order to increase usable space, provide shelter, provide cover, reduce the potential for tampering, and/or increase the visibility of the system for marketing purposes. The RDSA may be initially deployed at an elevation that facilitates deployment while allowing personnel to work safely from the ground before raising it in accordance with this embodiment of the invention. Persons of ordinary skill in the art will appreciate that the entire deployed RDSA can be elevated and can supported by any number of support structures.

The cable suspension upright members 44 may be lifted from their stowed position shown in FIG. 1 to their deployed upright position shown in FIG. 5A in several different ways. The cable suspension upright members 44 may be manually deployed or may be winched into place. FIG. 3 shows a winch motor 80 from which a winch cable (not shown) may be attached to the cable suspension upright member 44 after passing through pulley 82. Persons of ordinary skill in the art will appreciate that other mechanisms, such as pneumatic or hydraulic rams can be used to deploy the cable suspension upright members 44.

The RDSA of the present invention has numerous uses. A non-exhaustive list of possible uses of the RDSA include electric vehicle charging, remote solar power generation, covered parking structures, covered habitable spaces, solar powered advertising displays, remote agricultural sites, remote charging sites, etc.

The RDSA system of the present invention may be transported in its stowed configuration to the site in the location and orientation where it is desired to be deployed.

As disclosed herein, the cable suspension upright members 44 that are used to support the cantilever solar panel assembly support beams 56 are deployed and locked into their vertical positions. The cantilever solar panel assembly support beams 56 are then suspended from the cable suspension upright members 44 and rotated into their respective deployed locations. The solar panel assembly frames 24 are then positioned into their respective locations along the cantilever solar panel assembly support beams 56, are latched into place, and then pivoted to an angle selected to optimize solar collection. After deployment, the entire structure may, in some embodiments, be elevated using actuators, in the form of, for example, hydraulic or pneumatic rams, electric or hand winches, or jacks, acting on the support structure. In one embodiment, jacks (not shown) may be provided to extend downwardly from the ends of the cantilever solar panel assembly support beams 56 to contact the ground to help stabilize the deployed RDSA.

Although the present invention has been discussed in considerable detail with reference to certain preferred embodiments, other embodiments are possible. Therefore, the scope of the appended claims should not be limited to the description of preferred embodiments contained in this disclosure.

What is claimed is:

1. A deployable solar array comprising:
a rectangular support frame structure;
a first pair of end-support members mounted to opposite ends of the rectangular support frame at a first side thereof, each rotatable from a stowed position completely within the rectangular support frame structure to a horizontal deployed position;
a second pair of end-support members mounted to opposite ends of the rectangular support frame at a second side thereof opposite the first side, each rotatable from a stowed position completely within the rectangular support frame structure to a horizontal deployed position;
a plurality of solar panel assemblies, each solar panel assembly including a plurality of photovoltaic solar cell arrays arranged in a plane and having a height less than a height of the rectangular frame and a width less than the width of the rectangular frame, the plurality of solar panel assemblies vertically stacked parallel to one another in stowed positions within a volume defined by the rectangular frame, a first group of the solar panel assemblies being individually moveable along and supported by the first pair of end support members from their stowed positions to deployed positions, and a second group of the solar panel assemblies being individually moveable along and supported by the second pair of end support members from their stowed positions to deployed positions.

2. The deployable solar array of claim 1 wherein each solar panel assembly is rotatable along an axis perpendicular to the pair of end support members by which it is supported.

3. The deployable solar array of claim 1 wherein the rectangular support frame structure has length, width, and height dimensions that are no more than length, width, and height external dimensions of an intermodal freight shipping container described in ISO 668 international standard.

4. The deployable solar array of claim 1, further comprising:
a first vertical suspension column mounted to a first end support of the rectangular support frame and rotatable from a stowed position completely within the volume defined by the rectangular support frame structure to a vertical deployed position;
a second vertical suspension column mounted to a second end support of the rectangular support frame opposite the first end support and rotatable from a stowed position completely within the volume defined by the rectangular support frame structure to a vertical deployed position;
at least one first support cable connected between the first vertical suspension column and a first one of the first pair of end support members when the first one of the first end-support members is in its deployed position;
at least one second support cable connected between the first vertical suspension column and a first one of the second pair of end support members when the first one of the second end-support members is in its deployed position;
at least one third support cable connected between the first vertical suspension column and a second one of the first pair of end support members when the second one of the first end-support members is in its deployed position; and
at least one fourth support cable connected between the first vertical suspension column and a second one of the second pair of end support members when the second one of the second end-support members is in its deployed position.

5. The deployable solar array of claim 1 wherein the rectangular support frame structure includes a raising mechanism.

6. The deployable solar array of claim 5 wherein the raising mechanism is configured to raise the rectangular support structure to a height to accommodate a vehicle underneath the rectangular support structure.
